(19) United States
(12) Patent Application Publication
(10) Pub. No.: US 2007/0296092 A1
(43) Pub. Date: Dec. 27, 2007

(54) Pixel circuit

(75) Inventor: Jiunn-Yau Huang, Tainan County (TW)

Correspondence Address: RABIN & Berdo, PC, 1101 14TH STREET, NW, SUITE 500, WASHINGTON, DC, 20005, US

(73) Assignee: HIMAX TECHNOLOGIES LIMITED, Tainan County (TW)

(21) Appl. No.: 11/802,494

(22) Filed: May 23, 2007

(30) Foreign Application Priority Data
Jun. 27, 2006 (TW) 95123206

(51) Int. Cl. H01L 27/15; H01L 51/00

(52) U.S. Cl. 257/E51.022; 257/103; 257/79

(57) ABSTRACT

A pixel circuit includes a LED, first switch, second switch, first transistor, second transistor and capacitor. The LED has a first end receiving a first supply voltage. The first switch has a first terminal receiving a data signal and a control terminal receiving a scan signal. The second switch has a first terminal coupled to a second terminal of the first switch and a control terminal receiving the scan signal. The first transistor has a drain coupled to a second terminal of the second switch, a source receiving a second supply voltage and a gate coupled to the second terminal of the first switch. The second transistor has a drain coupled to the LED, a source receiving the second supply voltage, and a gate coupled to the first transistor. The capacitor has a first end coupled to the second transistor and a second end receiving the second supply voltage.

This application claims the benefit of Taiwan application Serial No. 95123206, filed Jun. 27, 2006, the subject matter of which is incorporated herein by reference.

### BACKGROUND OF THE INVENTION

1. Field of the Invention

The invention relates in general to a pixel circuit, and more particularly to an active matrix organic light emitting diode (AMOLED) pixel circuit using two switches, two transistors and a capacitor.

2. Description of the Related Art

Referring to FIG. 1, a circuit diagram of a conventional pixel circuit is shown. A pixel circuit 10, which is an AMOLED pixel circuit, includes a first switch T1, a second switch T2, a first transistor T3, a second transistor T4, a capacitor C and a light emitting diode (LED) 12. For example, the first switch T1, the second switch T2, the first transistor T3 and the second transistor T4 are p-type metal oxide semiconductor (PMOS) transistors, and the LED 12 is an organic light emitting diode (OLED).

The first switch T1 has a first terminal for receiving a data signal Data, and a control terminal for receiving a first scan signal Scan1. The first transistor T3 has a drain coupled to a second terminal of the first switch T1, a source for receiving an operational voltage VDD and a gate coupled to the second terminal of the first switch T1. The second switch T2 has a first terminal coupled to the gate of the first transistor T3 and a control terminal for receiving a second scan signal Scan2. The second transistor T4 has a drain coupled to an anode of the LED 12, a source coupled to a source of the first transistor T3 and a gate coupled to a second terminal of the second switch T2. The capacitor C has a first end coupled to the gate of the second transistor T4 and a second end coupled to the source of the second transistor T4.

However, alternative configurations of the conventional pixel circuit are necessary for a flexible layout or structure to improve the performance of the pixel circuit.

### SUMMARY OF THE INVENTION

The invention is directed to a pixel circuit driving a LED to produce the corresponding luminance by using a current mirror circuit structure.

According to a first aspect of the present invention, a pixel circuit is provided. The pixel circuit comprises a LED, a first switch, a second switch, a first transistor, a second transistor and a capacitor. The LED has a first end for receiving a first supply voltage. The first switch has a first terminal for receiving a data signal and a control terminal for receiving a scan signal. The second switch has a first terminal coupled to a second terminal of the first switch and a control terminal for receiving the scan signal. The first transistor has a drain coupled to a second terminal of the second switch, a source for receiving a second supply voltage and a gate coupled to the second terminal of the first switch. The second transistor has a drain coupled to a second end of the LED, a source for receiving the second supply voltage, and a gate coupled to the gate of the first transistor. The capacitor has a first end coupled to the gate of the second transistor and a second end for receiving the second supply voltage.

According to a second aspect of the present invention, a pixel circuit is provided. The pixel circuit comprises a LED, a first switch, a second switch, a first transistor, a second transistor and a capacitor. The LED has a first end for receiving a first supply voltage. The first switch has a first terminal for receiving a data signal and a control terminal for receiving a scan signal. The second switch has a first terminal coupled to a second terminal of the first switch and a control terminal for receiving the scan signal. The first transistor has a drain coupled to a second terminal of the second switch, a source for receiving a second supply voltage and a gate coupled to the second terminal of the first switch. The second transistor has a drain coupled to a second end of the LED, a source for receiving the second supply voltage, and a gate coupled to the gate of the first transistor. The capacitor has a first end coupled to the gate of the second transistor and a second end for receiving the first supply voltage.

The invention will become apparent from the following detailed description of the preferred but non-limiting embodiments. The following description is made with reference to the accompanying drawings.

### BRIEF DESCRIPTION OF THE DRAWINGS

FIG. 1 is a circuit diagram of a conventional pixel circuit.

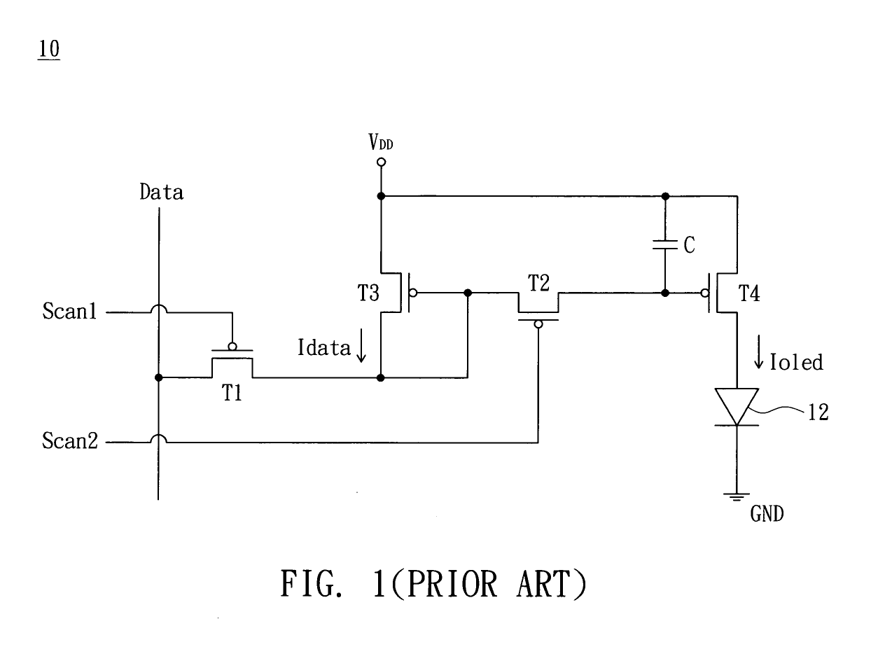

FIG. 2 is a circuit diagram of a pixel circuit according to a first embodiment of the invention.

FIG. 3 is a circuit diagram of a pixel circuit according to a second embodiment of the invention.

FIG. 4 is a circuit diagram of a pixel circuit according to a third embodiment of the invention.

FIG. 5 is a circuit diagram of a pixel circuit according to a fourth embodiment of the invention.

### DETAILED DESCRIPTION OF THE INVENTION

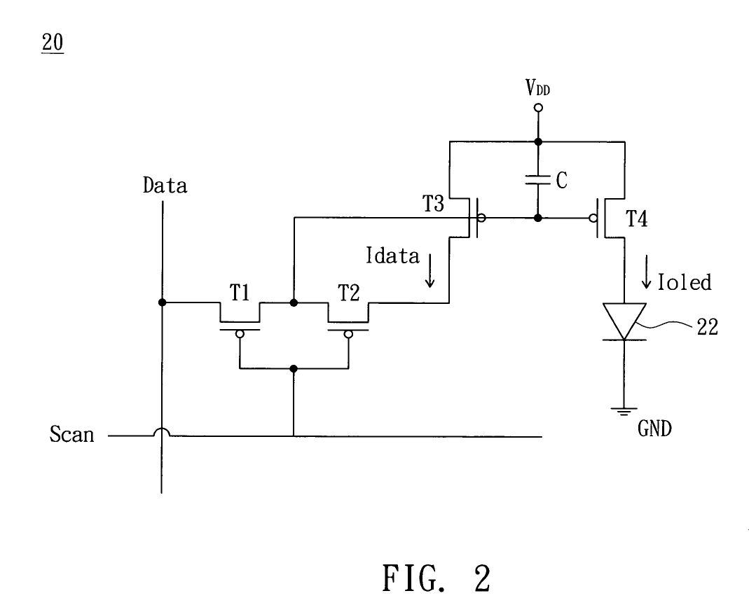

The invention provides an AMOLED pixel circuit driving an LED to produce the corresponding luminance by using a current mirror circuit structure. Referring to FIG. 2, a circuit diagram of a pixel circuit according to a first embodiment of the invention is shown. A pixel circuit 20, which is an AMOLED pixel circuit, includes a first switch T1, a second switch T2, a first transistor T3, a second transistor T4, a capacitor C and a LED 22. For example, the first switch T1, the second switch T2, the first transistor T3 and the second transistor T4 are PMOS transistors, and the LED 22 is an OLED.

The first switch T1 has a first terminal for receiving a data signal Data, and a control terminal for receiving a scan signal Scan. The second switch T2 has a first terminal coupled to a second terminal of the first switch T1 and a control terminal for receiving the scan signal Scan. The first transistor T3 has a drain coupled to a second terminal of the second switch T2, a source for receiving a second supply voltage, such as an operational voltage VDD and a gate coupled to a second terminal of the first switch T1.

The second transistor T4 has a drain coupled to an anode of the LED 22, a source for receiving the operational voltage VDD, and a gate coupled to the gate of the first transistor T3. The LED 22 has a cathode for receiving a first supply voltage, such as a ground voltage GND. The capacitor C has a first end coupled to the gate of the second transistor T4 and a second end for receiving the operational voltage VDD.

During a writing timing stage, the scan signal Scan turns on the first switch T1 and the second switch T2 and thus the first transistor T3 generates a data current Idata according to the data signal Data via the turned-on first switch T1 and the second switch T2. At the same time, owing that the second transistor T4 and the first transistor T3 form a current mirror circuit, the second transistor T4 generates a pixel current Ioled proportional to the data current Idata, and outputs the pixel current Ioled to the LED 22 to produce the corresponding luminance. During the writing timing stage, the capacitor C is charged via the turned-on first switch T1 to store the corresponding data voltage Vdata stably.

During a display timing stage, the scan signal Scan turns off the first switch T1 and the second switch T2, and consequently, the first transistor T3 is also turned off and the second transistor T4 is no longer electrically coupled to the data signal Data. However, owing that the capacitor C stably stores the data voltage Vdata, the second transistor T4 still outputs the pixel current Ioled to the LED 22 to produce the corresponding luminance.

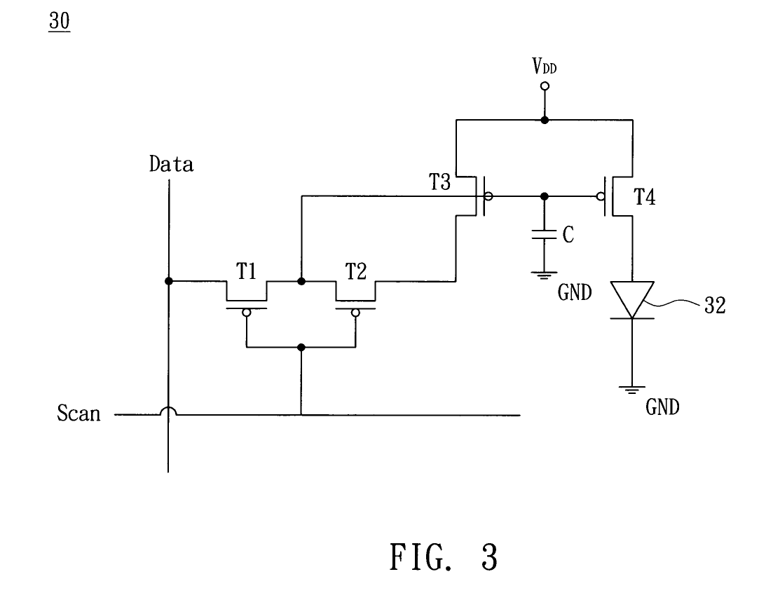

In the above pixel circuit 20, the configuration of the capacitor C is not limited to having a first end coupled to the gate of the second transistor T4 and a second end for receiving the operational voltage VDD. Referring to FIG. 3, a circuit diagram of a pixel circuit according to a second embodiment of the invention is shown. In a pixel circuit 30, the capacitor C has a first end coupled to the gate of the second transistor T4 and a second end for receiving the ground voltage GND. As a result, the capacitor C can maintain the data voltage Vdata such that the second transistor T4 can still output the pixel current Ioled to the LED 32 to produce the corresponding luminance. The other parts of the circuit structure and its operational principle are the same as those of the pixel circuit 20 in FIG. 2, and thus any detail is not necessary to be given here.

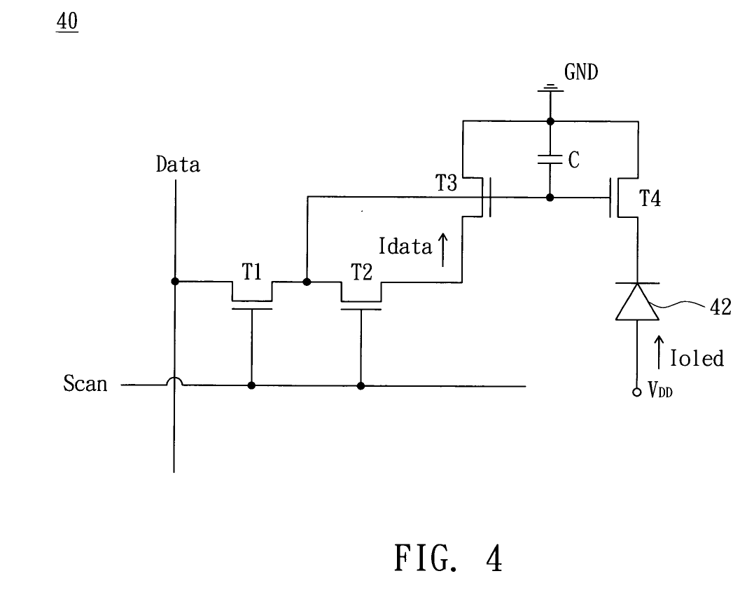

In the AMOLED pixel unit of the invention, the first switch T1, the second switch T2, the first transistor T3 and the second transistor T4 can also be n-type metal oxide semiconductor (NMOS) transistors. Referring to FIG. 4, a circuit diagram of a pixel circuit according to a third embodiment of the invention is shown. A pixel circuit 40 has a similar circuit structure as compared to the pixel circuit 20 of FIG. 2. The only difference of the pixel circuit 40 from the pixel circuit 20 lies in the second supply voltage received by the sources of the first transistor T3 and the second transistor T4 is the ground voltage GND. Besides, the second transistor T4 has a drain coupled to a cathode of the LED 42 and the first supply voltage received by the an anode of the LED 42 is the operational voltage VDD.

During a writing timing stage, the scan signal Scan turns on the first switch T1 and the second switch T2 and a data current Idata is inputted to the first transistor T3 via the turned-on first switch T1 and the second switch T2 according to the data signal Data. At the same time, owing that the second transistor T4 and the first transistor T3 form a current mirror circuit, the second transistor T4 generates a pixel current Ioled proportional to the data current Idata, and outputs the pixel current Ioled to the LED 42 to produce the corresponding luminance. During the writing timing stage, the capacitor C is charged via the turned-on first switch T1 to store the corresponding data voltage Vdata stably.

During a display timing stage, the scan signal Scan turns off the first switch T1 and the second switch T2, and consequently, the first transistor T3 is also turned off and the second transistor T4 is no longer electrically coupled to the data signal Data. However, owing that the capacitor C stably stores the data voltage Vdata, the second transistor T4 still outputs the pixel current Ioled to the LED 42 to produce the corresponding luminance.

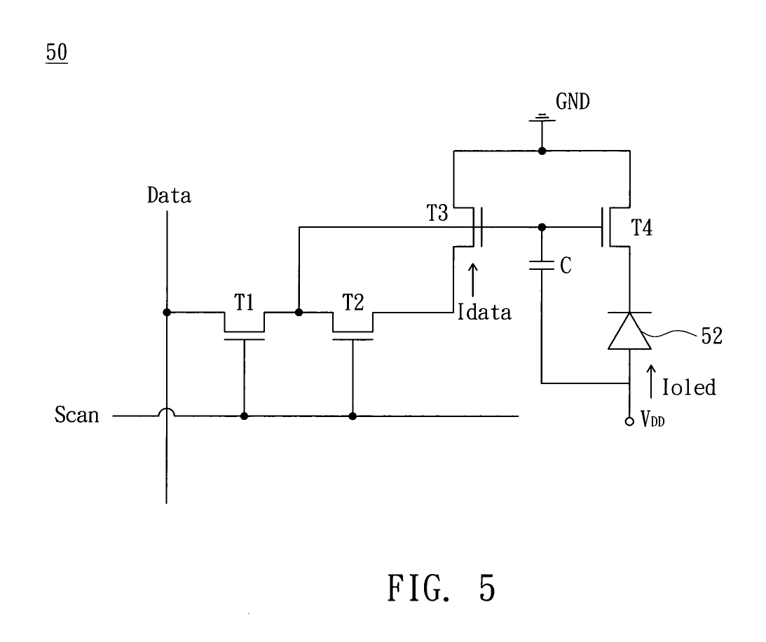

In the above pixel circuit 40, the configuration of the capacitor C is not limited to having a first end coupled to the gate of the second transistor T4 and a second end for receiving the ground voltage GND. Referring to FIG. 5, a circuit diagram of a pixel circuit according to a fourth embodiment of the invention is shown. In a pixel circuit 50, the capacitor C has a first end coupled to the gate of the second transistor T4 and a second end for receiving the operational voltage VDD. As a result, the capacitor C can maintain the data voltage Vdata such that the second transistor T4 can still output the pixel current Ioled to the LED 52 to produce the corresponding luminance. The other parts of the circuit structure and its operational principle are the same as those of the pixel circuit 40 in FIG. 4, and thus any detail is not necessary to be given here.

The pixel circuit disclosed by the above embodiments of the invention drives the LED to produce the corresponding luminance by using a current mirror circuit structure and maintains the LED to have the luminance during the displaying timing stage.

While the invention has been described by way of example and in terms of four embodiments, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A pixel circuit, comprising:
a light emitting diode (LED), having a first end for receiving a first supply voltage;
a first switch, having a first terminal for receiving a data signal and a control terminal for receiving a scan signal;
a second switch, having a first terminal coupled to a second terminal of the first switch and a control terminal for receiving the scan signal;
a first transistor, having a drain coupled to a second terminal of the second switch, a source for receiving a second supply voltage and a gate coupled to the second terminal of the first switch;
a second transistor, having a drain coupled to a second end of the LED, a source for receiving the second supply voltage, and a gate coupled to the gate of the first transistor; and
a capacitor, having a first end coupled to the gate of the second transistor and a second end for receiving the second supply voltage.

2. The pixel circuit according to claim 1, wherein the first switch, the second switch, the first transistor and the second transistor are all p-type metal oxide semiconductor (PMOS) transistors, the first end of the LED is a cathode, the second end of the LED is an anode, the first supply voltage is a ground voltage and the second supply voltage is an operational voltage.

3. The pixel circuit according to claim 1, wherein the first switch, the second switch, the first transistor and the second transistor are all n-type metal oxide semiconductor (NMOS) transistors, the first end of the LED is an anode, the second end of the LED is a cathode, the first supply voltage is an operational voltage and the second supply voltage is a ground voltage.

4. The pixel circuit according to claim 1, wherein the LED is an organic light emitting diode (OLED).

5. A pixel circuit, comprising:
a LED, having a first end for receiving a first supply voltage;
a first switch, having a first terminal for receiving a data signal and a control terminal for receiving a scan signal;
a second switch, having a first terminal coupled to a second terminal of the first switch and a control terminal for receiving the scan signal;
a first transistor, having a drain coupled to a second terminal of the second switch, a source for receiving a second supply voltage and a gate coupled to the second terminal of the first switch;
a second transistor, having a drain coupled to a second end of the LED, a source for receiving the second supply voltage, and a gate coupled to the gate of the first transistor; and
a capacitor, having a first end coupled to the gate of the second transistor and a second end for receiving the first supply voltage.

6. The pixel circuit according to claim 5, wherein the first switch, the second switch, the first transistor and the second transistor are all PMOS transistors, the first end of the LED is a cathode, the second end of the LED is an anode, the first supply voltage is a ground voltage and the second supply voltage is an operational voltage.

7. The pixel circuit according to claim 5, wherein the first switch, the second switch, the first transistor and the second transistor are all NMOS transistors, the first end of the LED is an anode, the second end of the LED is a cathode, the first supply voltage is an operational voltage and the second supply voltage is a ground voltage.

8. The pixel circuit according to claim 5, wherein the LED is an organic light emitting diode (OLED).
